(19) United States
(12) Patent Application Publication
(10) Pub. No.: US 2010/0003835 A1
(43) Pub. Date: Jan. 7, 2010

(54) Low-K Precursors Based on Silicon Cryptands, Crown Ethers and Podands

(75) Inventors: James J.F. McANDREW, Glen Mills, PA (US); Christian Dussarrat, Wilmington, DE (US)

Correspondence Address: AIR LIQUIDE;Intellectual Property, 2700 POST OAK BOULEVARD, SUITE 1800, HOUSTON, TX, 77056, US

(73) Assignee: American Air Liquide, Inc., Fremont, CA (US)

(21) Appl. No.: 12/497,293

(22) Filed: Jul. 2, 2009

Related U.S. Application Data
(60) Provisional application No. 61/078,039, filed on Jul. 3, 2008.

(51) Int. Cl. H01L 21/314

(52) U.S. Cl. 438/778; 257/E21.266

(57) ABSTRACT

Disclosed herein is the use of a silicon podand, silicon crown ether, or silicon cryptand to form a low-k dielectric film on a substrate.

### CROSS REFERENCE TO RELATED APPLICATIONS

The present application claims the benefit of U.S. Provisional Application Ser. No. 61/078,039 filed Jul. 3, 2008, herein incorporated by reference in its entirety for all purposes.

### BACKGROUND

Insulating films that simultaneously provide adequate mechanical strength with low dielectric constant (“low-k”) are required for semiconductor manufacturing (see for example International Technology Roadmap for Semiconductors, 2007 edition). In recent years, the most successful materials have been carbon-doped silicon oxides containing Si, C, O and H (i.e. “SiCOH”), deposited by Plasma-Enhanced Chemical Vapor Deposition (PECVD), as described for example in U.S. Pat. Nos. 7,030,468 and 7,282,458 (both Gates et al.). A major advantage of these materials is that they can be deposited using vapor deposition equipment similar to that in general use for depositing SiO₂ dielectrics. Silane or tetraethoxysilane (TEOS) are widely used precursors for SiO₂ deposition, whereas exemplary precursors used for SiCOH deposition include, for example, diethoxymethylsilane and related compounds, as described in U.S. Pat. No. 6,583,048, tetramethyl cyclotetrasilozane [TMCTS] as described in U.S. Pat. No. 6,479,110, and related compounds as in U.S. Pat. No. 7,030,468.

In US 2006/0165891, Edelstein et al. claim a method of fabricating a SiCOH dielectric material wherein the dielectric film has a covalently-bonded tri-dimensional network structure in which a fraction of the C atoms are bonded as Si—CH3 functional groups and another fraction of the C-atoms are bonded as Si—R—Si wherein R is phenyl, —[CH₂]ₙ— or [S]ₙ (sic), where n≧1. An extensive list of precursors is claimed for preparation of these films, and some examples are given. Nonetheless, it is not yet clear which of the listed precursors is most suitable for deposition of films with the desired properties. Sugahara et al (U.S. Pat. No. 5,989,998) claim the use of phenyl or vinyl substituents on Si precursors, but limited to the case where the remaining substituents are alkoxy groups.

Replacement of O in the Si—O—Si groups of the typical SiCOH matrix by methylene or longer alkylene groups (i.e. Si—(CH₂)ₙ—Si) was proposed by Sugahara et al. [Jpn. J. Applied Physics, 38 1428 (1999); J. Electrochem. Soc. 148(6) F120-126 (2001)]. While this approach allows greater mechanical strength to be achieved for lower dielectric constant films, the precursor proposed by Sugahara et al., Cl₃SiCH₂SiCl₃, will unfortunately tend to introduce Si—Cl groups into the deposited film, which in turn will tend to hydrolyze on contact with ambient water vapor to Si—OH. Additionally, both Si—Cl and Si—OH are hydrophilic and therefore promote water absorption by the film, leading to an increase in dielectric constant as well as, potentially, mechanical problems. Therefore there is a need for precursors better suited to deposition of these Si—(CH₂)ₙ—Si films.

While Si—(CH₂)ₙ—Si film incorporation allows lower dielectric constant films with improved mechanical properties to be achieved, the dielectric constant may be further reduced by using a porogen to introduce porosity, as in, for example U.S. Pat. No. 7,288,292 (also Gates et al.) and U.S. Pat. No. 6,846,515 (Vrtis et al.). However, porous films are less mechanically strong, which has significantly impeded the adoption of porous low-k films into manufacturing.

While porosity may be introduced using conventional porogens, for example as described in U.S. Pat. Nos. 7,288,292 and 6,846,515 mentioned above, many conventional porogens (such as norbornadiene, also known as bicycloheptadiene) are difficult to handle because they tend to polymerize, leading, for example, to clogging of vaporizers.

Vinyl tris(2-methoxyethoxy)silane, shown below, has been used for cross-linking polyethylene and reinforcing electrical cable insulation. Neither of those applications is related to deposition of low-k dielectrics, although they do help ensure that this material is readily available at reasonable cost. Uchimoto et al. (J. Electrochem. Soc. 137(1) 35 (1990)) deposited films of this material by PECVD using a capacitively coupled parallel plate reactor. These films were then doped with lithium ions in order to prepare an ionically conductive polymer film on a metal or glass substrate for use in solid-state lithium batteries, sensors, and display devices. The present application is directed towards the use of related films in a completely different fashion, namely as a non-conductive dielectric layer on a silicon semiconductor substrate.

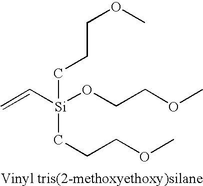

There is a need for precursors suitable for use in deposition of low-dielectric-constant films with good mechanical properties, and preferably precursors leading to porous films without the need for a separate porogen molecule.

### SUMMARY

Disclosed herein are methods of forming a low dielectric constant insulating layer on a substrate and subsequently rendering it porous. Also disclosed is the film coated substrate formed by those methods.

In one embodiment, a low-k dielectric film is formed on a substrate by providing the substrate, providing at least one precursor selected from the group consisting of silicon podands, silicon crown ethers, and silicon cryptands, and forming the low-k dielectric film on the substrate.

Alternatively, the low-k dielectric film may be formed on a substrate by providing a reaction chamber having at least one substrate disposed therein, introducing into the reaction chamber at least one precursor compound selected from the group consisting of silicon podands, silicon crown ethers, and silicon cryptands, contacting the at least one precursor compound and the substrate to form the low-k dielectric film on at least one surface of the substrate using a vapor deposition process, wherein a thin layer of a Group I metal ion salt is not subsequently deposited on the low-k dielectric film.

Either method may include one or more of the following aspects:
the precursor having a ratio of oxygen atoms to silicon atoms of at least 2:1;
the precursor having a ratio of oxygen atoms to silicon atoms of at least 4:1;
the precursor having a ratio of oxygen atoms to silicon atoms of at least 6:1;
the precursor being vinyltris(2-methoxyethoxy)silane; and
subsequently heating or curing the low-k dielectric film.

The low-k dielectric film coated substrate may include one or more of the following aspects:
being formed by either method disclosed above, including any or all of the optional aspects;
being rendered porous by heating or curing;
having a dielectric constant below about 3;
having a dielectric constant below about 2.5;
having a Young's modulus greater than about 5 GPa; and
having a Young's modulus greater than about 7 GPa.

### Notation and Nomenclature

The following abbreviated terms are used throughout the description and claims.

As used herein, the abbreviation “MIM” refers to Metal Insulator Metal (a structure used in capacitors); the abbreviation “DRAM” refers to dynamic random access memory; the abbreviation “FeRAM” refers to ferroelectric random access memory; and the abbreviation “CMOS” refers to complementary metal-oxide-semiconductor.

### BRIEF DESCRIPTION OF THE DRAWINGS

For a further understanding of the nature and objects of the present invention, reference should be made to the following detailed description, taken in conjunction with the accompanying drawings, and wherein:

FIG. 1 is a graphical representation of the expected polymerization of vinyltris(2-methoxyethoxy)silane.

FIG. 2 is an illustration of an exemplary plasma-enhanced chemical vapor deposition apparatus used to form a low-k dielectric film on a substrate.

### DESCRIPTION OF PREFERRED EMBODIMENTS

Despite extensive study of many candidate silicon molecules for low-k dielectric film deposition, one class that has not been examined is that of silicon podands, silicon crown ethers, and silicon cryptands, shown below. In each of these types of molecule, the central Si atom is bound via multiple Si—O— linkages to ethers. In a podand, one or more ether chains each have one oxygen atom bound to a silicon atom. In a crown ether, a single ether chain has two oxygen atoms at opposite ends of the ether chain bound to a single silicon atom, creating a cyclic compound. In a cryptand, three ether chains are each bonded at one end to one silicon atom each through an oxygen atom. Each chain terminates at an oxygen atom bonded to a carbon atom at some point either at the end or in the middle of a C1 to C10 alkyl chain. In one embodiment, all three chains terminate at a single carbon atom. Cryptands are so called because they form a cavity which can act as a “crypt” for another species, e.g. an ion. Podands and crown ethers may act in the same way, though to a lesser extent.

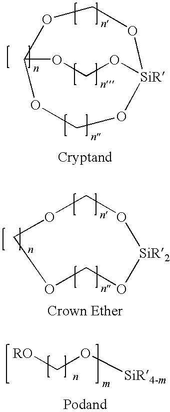

In the molecular structures, m is ≦4; n, n′, n″, and n′″ may be the same or different and ≧1; R may be a C1 to C10 alkyl chain; and R′ may be H, an alkyl group, an alkenyl group, an alkynyl group, an aryl group, or an alkoxy group, any of which may or may not be substituted, including substitution with an ether group. As volatile compounds are recommended for the vapor deposition purposes, n, n′, n″, and n′″ may preferably be 3 or less. For similar reasons, R in the podand structure may preferably be a methyl or ethyl group. Preferably R′ includes a vinyl substituent, or a different alkenyl or alkynyl substituent, or a phenyl substituent, to facilitate formation of Si—CH₂—CH₂—Si linkages, for example by polymerization of the vinyl group. Preferably, the precursor will have a ratio of oxygen to silicon atoms of at least 2:1, more preferably 4:1, and even more preferably 6:1.

Silicon podands, crown ethers, or cryptands in which the R′ group is a methyl or other alkyl group may provide additional porosity (and hence a lower k) by substituting for the oxygen in the Si—O—Si linkages in the structure and may therefore be advantageous in certain applications. See infra, Sugahara et al. In the case of a prior art precursor, namely tetramethylcyclotetrasiloxane, incorporation of porogens has been found to proceed through reaction with Si—H (A. Grill and D. Neumeyer, J. Appl. Phys. 94(10) 6697-6707 (2003)). Therefore, the use of H as R′ directly bonded to Si may also be advantageous for the present class of precursors either alone or when combined with other porogens.

The podand, crown-ether, or cryptand precursor may also be used as a porogen in combination with another precursor. Similarly, a separate porogen may be combined with the podand, crown-ether, or cryptand precursor disclosed herein in order to enhance pore-formation. Examples of some potential porogens are described in WO 2007/113104 (Deval and Vautier) and U.S. Pat. No. 6,479,110.

Without being bound by any particular theory, Applicants theorize that the ring and cage structures in silicon crown ethers and silicon cryptands introduce significant but largely uniform porosity into a dielectric film when the film is subsequently cured. Silicon podands may work in a similar way by forming ring structures after deposition.

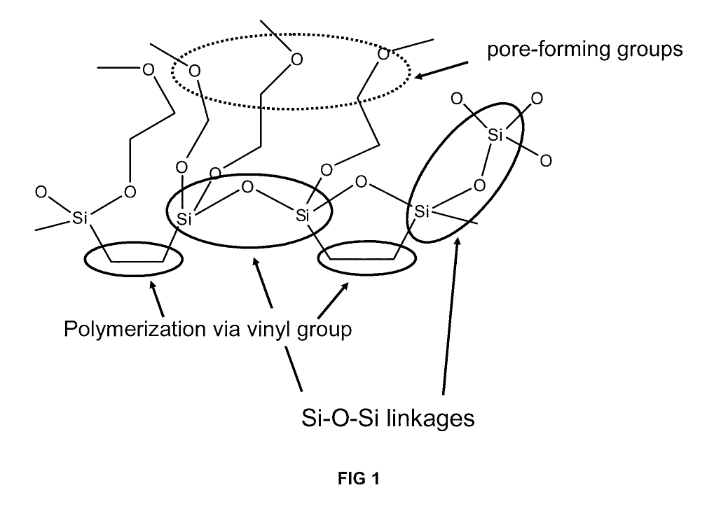

Vinyltris(2-methoxyethoxy)silane, shown below, is an example of a silicon podand in which there are three (3) Si—O— linked ether substituents and R′ is a vinyl group. Polymerization of this molecule under mild plasma conditions is expected to occur by polymerization at both the vinyl group and the Si—O linkages, as shown in FIG. 1. Note that polymerization via the vinyl group results in a Si—CH₂—CH₂—Si linkage even though there is no such linkage in the parent compound. The Si—O— linked ether groups occupy significant space within the film. It is believed that these groups will be relatively easy to remove in a subsequent heating or curing step resulting in pore formation, but that the extent to which the Si—O—Si and Si—CH₂—CH₂—Si chains can re-arrange on their removal will be limited. The subsequent pore formation via a heating or curing step may include thermal annealing, ultraviolet (UV) treatment, plasma treatment, or electron beam treatment (as described for example in U.S. Pat. No. 7,030,468, the method of which is incorporated by reference herein in its entirety). Analogous crown-ethers or cryptands are expected to behave similarly.

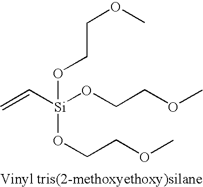

### Use of Composition

The podand, crown-ether, or cryptand precursor may be used to form an insulating film on a silicon substrate, which may or may not already include other layers thereon, by deposition processes known in the art. Exemplary, but non-limiting reference to the vapor deposition processes disclosed in U.S. Pat. Nos. 6,312,793, 6,479,110, 6,756,323, 6,846,515, 6,953,984, 7,030,468, 7,049,427, 7,202,564, 7,282,458, 7,288,292, 7,312,524, 7,521,377 and U.S. Pat. App. Pub. No. 2007/0057235 is incorporated herein by reference. The podand, crown-ether, or cryptand precursor may be used alone, as described in, for example, U.S. Pat. No. 7,202,564, or in combination with an added porogen, as described in U.S. Pat. Nos. 6,312,793, 6,479,110, 7,030,468 and 7,282,458. In either case, post-treatment to form pores may include thermal annealing, ultraviolet (UV) treatment, plasma treatment, or electron beam treatment (as described for example in U.S. Pat. No. 7,030,468). Any of the above post-treatment methods, but especially UV treatment, has been found effective to increase cross-linking of the film by converting residual SiOC and SiOH linkages to SiOSi. This in turn tends to improve the mechanical strength of the film. In addition, post treatment, and particularly, UV curing has been found effective for removal of residual organic material, leading to the creation of pores and a decrease in dielectric constant.

For example, it is anticipated that, in the method disclosed of forming a layer of carbon-doped silicon oxide on a substrate in U.S. Pat. No. 7,202,564, the compounds disclosed herein may replace the cyclic or non-cyclic organosilicon compounds mentioned (which include as examples octamethylcyclotetrasiloxane [OMCTS], dimethyldimethoxysilane [DMDMOS], etc.)

The silicon substrate, which may or may not include additional layers, is placed in the reaction chamber of a vapor deposition tool. The podand, crown-ether, or cryptand precursor used to form the low-k dielectric film may be delivered as a liquid vaporized directly within the reactor, or transported by an inert carrier gas including, but not limited to, helium or argon. A porogens precursor may optionally be similarly delivered, as described in the art (see above references) in addition to, optionally, an oxidizing gas such as oxygen.

Preferably, the podand, crown-ether, or cryptand precursor is vaporized at a temperature chosen so as to provide sufficient vapor pressure of the precursor while avoiding its decomposition. Optionally, the precursor may be dissolved in a suitable solvent to facilitate its evaporation. Suitable solvents include hydrocarbons such as hexane, octane, etc. Alternatively, the precursor may be dissolved in a second organosilane compound such as dimethyidimethoxysilane, diethoxymethylsilane, tetramethylsilane, octamethylcyclotetrasiloxane, etc. In this case both the precursor and the second organosilane compound will contribute to film formation.

The low-k dielectric layer will be deposited upon a silicon substrate, which may include one or more layers thereon prior to deposition of the low-k dielectric layer, depending on the final use intended. In some embodiments, the substrate may include doped or undoped silicon optionally coated with a silicon oxide layer, in addition to oxides which are used as dielectric materials in MIM, DRAM, FeRam technologies or gate dielectrics in CMOS technologies (for example, SiO₂, SiON, or HfO₂ based materials, TiO₂ based materials, ZrO₂ based materials, rare earth oxide based materials, ternary oxide based materials, etc.), and metals that are used as conducting materials in such applications, such as for example, tungsten, titanium, tantalum, ruthenium, or copper. In other embodiments, the substrate may include copper interconnects and insulating regions, such as another low-k material, optionally coated with a sealing layer such as SiO₂ or SiN. Other examples of layers upon which the insulating film may be coated include, but are not limited to, solid layers such as metal layers (for example, Ru, Al, Ni, Ti, Co, Pt and metal silicides, such as TiSi₂, CoSi₂, and NiSi₂); metal nitride containing layers (for example, TaN, TiN, WN, TaCN, TiCN, TaSiN, and TiSiN); semiconductor materials (for example, Si, SiGe, GaAs, InP, diamond, GaN, and SiC); insulators (for example, SiO₂, Si₃N₄, HfO₂, Ta₂O₅, ZrO₂, TiO₂, Al₂O₃, and barium strontium titanate); or other layers that include any number of combinations of these materials. The actual layers utilized will also depend upon the low-k dielectric layer utilized.

The podand, crown-ether, or cryptand precursor is introduced into the film deposition chamber and contacted with the substrate to form a low-k dielectric layer on at least one surface of the substrate. The film deposition chamber may be any enclosure or chamber of a device in which deposition methods take place, such as, without limitation, a parallel plate-type reactor, a cold-wall type reactor, a hot-wall type reactor, a single-wafer reactor, a multi-wafer reactor, or other such types of deposition systems.

Based upon the theoretical mechanism and the dielectric properties of films formed from organosilane compounds, it is believed that the layers deposited using the above precursors will have a dielectric constant below about 3 (relative to vacuum), and more preferably below about 2.5.

As mentioned above and discussed in more detail in the incorporated prior art, the low-k dielectric layer may be rendered porous by a subsequent heating or curing step to further reduce the dielectric constant and increase the mechanical strength of the insulating layer, usually before any additional layers are deposited. A suitable heating or curing step may include, but is not limited to, annealing, UV light, or electron beam. It is believed that the resulting porous film will preferably exhibit a Young's modulus greater than about 5 GPa, and more preferably greater than about 7 GPa.

Based upon Uchimoto et al., a thin layer of a Group I or Group II metal salt, such as LiClO₄, must not subsequently be deposited on the low-k dielectric film because such a layer, under the right conditions, is believed to convert the low-k dielectric film to a conductive film, contrary to the purpose of the disclosure herein.

Based on the disclosure herein, the references incorporated herein, and teachings well known to those skilled in the art, one of ordinary skill in the art would be able to easily select appropriate values for the process variables controlled during deposition of the low-k films, including RF power, precursor mixture and flow rate, pressure in reactor, and substrate temperature.

### EXAMPLE

The following example illustrates experiments performed in conjunction with the disclosure herein. The examples are not intended to be all inclusive and are not intended to limit the scope of disclosure described herein.

### Example

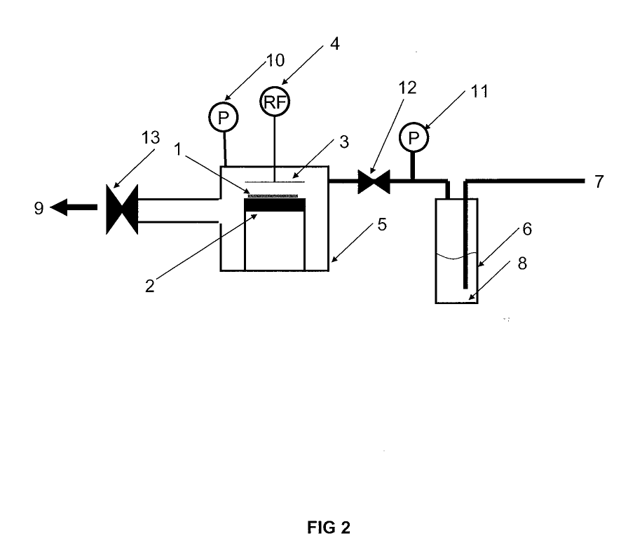

As depicted in FIG. 2, a silicon substrate 1 was loaded into a vacuum chamber 5 which was then closed and evacuated using a vacuum source 9, consisting of a vacuum pump and a liquid nitrogen cooled trap to collect waste precursor for eventual disposal. A sample of vinyltris(methoxy-ethoxy)silane precursor 8, about 30 grams, was loaded into a bubbler vessel 6, in a glove box (not shown) to protect the precursor 8 from air contamination. The vacuum chamber walls (not shown) were heated to about 100° C., while the upstream precursor delivery line and bubbler vessel 6 were maintained at lower temperatures. The substrate 1 was heated using the heater 2 to 50°, 150°, or 200° C., depending on the test. After thorough evacuation of the vacuum chamber 5, a carrier gas flow 7, namely 25 standard cc per minute of He gas, was provided to the bubbler vessel 6. The delivery valve 12 was adjusted until the delivery line pressure gauge 11 reached a suitable pressure of about 10 torr. The vacuum valve 13 was adjusted to give a chamber pressure of about 1 torr at the gauge 10. The RF power supply 4 was activated to supply 50 W at 13.56 MHz to the electrode 3, providing a plasma in the region above the substrate 1. After 5 minutes, the power was turned off. Films varying in thickness from about 0.5 to 1 μm were deposited on the substrate 1, as verified by measurement with an ellipsometer after removal from the chamber 5.

It will be understood that many additional changes in the details, materials, steps, and arrangement of parts, which have been herein described and illustrated in order to explain the nature of the invention, may be made by those skilled in the art within the principle and scope of the invention as expressed in the appended claims. Thus, the present invention is not intended to be limited to the specific embodiments in the examples given above and/or the attached drawings.

What is claimed is:

1. A method for producing a low-k dielectric film on a substrate comprising:
a) providing the substrate;
b) providing at least one precursor selected from the group consisting of silicon podands, silicon crown ethers, and silicon cryptands; and
c) forming the low-k dielectric film on the substrate.

2. The method of claim 1, wherein the at least one precursor has a ratio of oxygen atoms to silicon atoms of at least 2:1.

3. The method of claim 2, wherein the ratio is at least 4:1.

4. The method of claim 3, wherein the ratio is at least 6:1.

5. The method of claim 4, wherein the at least one precursor is vinyltris(2-methoxyethoxy)silane.

6. The method of claim 5, further comprising the step of heating or curing the low-k dielectric film.

7. A method of forming a low-k dielectric film on a substrate, the method comprising the steps of:
providing a reaction chamber having at least one substrate disposed therein;
introducing into the reaction chamber at least one precursor compound selected from the group consisting of silicon podands, silicon crown ethers, and silicon cryptands;
contacting the at least one precursor compound and the substrate to form the low-k dielectric film on at least one surface of the substrate using a vapor deposition process, wherein a thin layer of a Group I metal ion salt is not subsequently deposited on the low-k dielectric film.

8. The method of claim 7, wherein the at least one precursor has a ratio of oxygen to silicon of at least 6:1.

9. The method of claim 8, wherein the at least one precursor is vinyltris(2-methoxyethoxy)silane.

10. The method of claim 7, further comprising the step of heating or curing the low-k dielectric film.

11. A low-k dielectric film coated substrate comprising the product made by the method of claim 10.

12. The low-k dielectric film coated substrate of claim 11, wherein the at least one precursor is vinyltris(2-methoxyethoxy)silane.

13. The low-k dielectric film coated substrate of claim 11, wherein the low-k dielectric film has a dielectric constant below about 3.

14. The low-k dielectric film coated substrate of claim 13, wherein the low-k dielectric film has a dielectric constant below about 2.5.

15. The low-k dielectric film coated substrate of claim 11, wherein the low-k dielectric film has a Young's modulus greater than about 5 GPa.

16. The low-k dielectric film coated substrate of claim 15, wherein the low-k dielectric film has a Young's modulus greater than about 7 GPa.
